(19) United States
(12) Patent Application Publication
(10) Pub. No.: US 2025/0284456 A1
(43) Pub. Date: Sep. 11, 2025

(54) ODD AND EVEN BIT WEIGHT EQUALIZATION METHOD AND SYSTEM

(71) Applicant: ANPEC ELECTRONICS CORPORATION, HSINCHU (TW)

(72) Inventors: YU-YU CHANG, HSINCHU (TW); CHUANG-SHUN XU, HSINCHU (TW); JIA-HUA HONG, HSINCHU (TW)

(21) Appl. No.: 18/669,605

(22) Filed: May 21, 2024

(30) Foreign Application Priority Data
Mar. 11, 2024 (TW) 113108746

(51) Int. Cl. G06F 7/50; G06F 5/01

(52) U.S. Cl. CPC G06F 7/50; G06F 5/01

(57) ABSTRACT

An odd and even bit weight equalization method and system are provided. The method includes processes of: determining whether or not bit values are equal to a weight value; if not, setting even and odd initial bits, and if yes, setting a next even bit of an even bit to which an even bit position is last shifted previously as the even initial bit, and setting a next odd bit of an odd bit to which an odd bit position is last shifted previously; shifting the even bit position from the even initial bit to other even bits and shifting the odd bit position from the odd initial bit to other odd bits; and adjusting the even and odd initial bits, and the even and odd bits to which the even and odd bit positions are shifted, to be equal to the weight value.

### CROSS-REFERENCE TO RELATED PATENT APPLICATION

This application claims the benefit of priority to Taiwan Patent Application No. 113108746, filed on Mar. 11, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a data bit weight setting method and system, and more particularly to an odd and even bit weight equalization method and system.

### BACKGROUND OF THE DISCLOSURE

A data weighted averaging (DWA) algorithm is also known as an element rotation algorithm. The data weighted averaging algorithm is often used to overcome a problem of mismatch in a manufacturing process. However, the data weighted averaging (DWA) algorithm is difficult to achieve the aim of controlling a probability of selecting each of a plurality of components to be approximately equal to a probability of selecting any other one of the plurality of components during a conversion process.

### SUMMARY OF THE DISCLOSURE

In response to the above-referenced technical inadequacies, the present disclosure provides an odd and even bit weight equalization method. The odd and even bit weight equalization method is performed by an odd and even bit weight equalization circuit. The odd and even bit weight equalization method includes processes of: (a) determining whether or not an even number set for a weight setting program performed each time is equal to a zero value, in response to determining that the even number set for the weight setting program performed each time is equal to the zero value, directly performing the process (d), and in response to determining that the even number set for the weight setting program performed each time is not equal to the zero value, sequentially performing the processes (b) to (d); (b) in the weight setting program performed each time, determining whether or not any one of a plurality of bit values of a plurality of even bits of input data is equal to a first weight value, in response to determining that any one of the plurality of bit values of the plurality of even bits of the input data is not equal to the first weight value, setting one of the plurality of even bits of the input data as an even initial bit, and in response to determining that any one of the plurality of bit values of the plurality of even bits of the input data is equal to the first weight value, setting one of the plurality of even bits that is next to the even bit to which an even bit position is shifted last previously as the even initial bit; (c) in the weight setting program performed each time, subtracting a value “1” from the even number to obtain a value as an even bit shift number, shifting the even bit position from the even initial bit to one or more of the plurality of even bits by the even bit shift number, and adjusting the even initial bit and the one or more of the plurality of even bits to be equal to the first weight value; (d) determining whether or not an odd number set for the weight setting program performed each time is equal to a zero value, in response to determining that the odd number set for the weight setting program performed each time is equal to the zero value, returning to perform the process (a), and in response to determining that the odd number set for the weight setting program performed each time is not equal to the zero value, sequentially performing the processes (e) to (f); (e) in the weight setting program performed each time, determining whether or not any one of a plurality of bit values of a plurality of odd bits of the input data is equal to the first weight value, in response to determining that any one of the plurality of bit values of the plurality of odd bits of the input data is not equal to the first weight value, setting one of the plurality of odd bits of the input data as an odd initial bit, and in response to determining that any one of the plurality of bit values of the plurality of odd bits of the input data is equal to the first weight value, setting one of the plurality of odd bits that is next to the odd bit to which an odd bit position is last shifted previously as the odd initial bit; and (f) in the weight setting program performed each time, subtracting a value “1” from the odd number to obtain a value as an odd bit shift number, shifting the odd bit position from the odd initial bit to one or more of the plurality of odd bits by the odd bit shift number, adjusting the odd initial bit and the one or more of the plurality of odd bits to be equal to the first weight value, and then returning to perform the process (a).

In order to solve the above-mentioned problems, one of the technical aspects adopted by the present disclosure is to provide an odd and even bit weight equalization system. The odd and even bit weight equalization system includes a weight equalization circuit. The weight equalization circuit is configured to perform a weight setting program multiple times. In the weight setting program performed for the first time, the weight equalization circuit sets any one of a plurality of even bits of input data as an even initial bit. In the weight setting program performed for other times, the weight equalization circuit sets one of the plurality of even bits that is next to the even bit to which the even bit position is last shifted previously as the even initial bit. When an even number set for the weight setting program performed each time is not equal to a zero value, the weight equalization circuit subtracts a value “1” from the even number to obtain a value as an even bit shift number, shifts an even bit position from the even initial bit to one or more of the plurality of even bits by the even bit shift number, and adjusts the even initial bit and the one or more of the plurality of even bits to be equal to a first weight value. In the weight setting program performed for the first time, the weight equalization circuit sets any one of a plurality of odd bits of the input data as an odd initial bit. In the weight setting program performed for other times, the weight equalization circuit sets the bit value of one of the plurality of odd bits that is next to the odd bit to which the odd bit position is last shifted previously, as the odd initial bit. When an odd number set for the weight setting program performed each time is not equal to the zero value, the weight equalization circuit subtracts a value “1” from the odd number to obtain a value as an odd bit shift number, shifts an odd bit position from the odd initial bit to one or more of the plurality of odd bits by the odd bit shift number, and adjusts the odd initial bit and the one or more of the plurality of odd bits to be equal to the first weight value.

As described above, the present disclosure provides the odd and even bit weight equalization method and system. In the odd and even bit weight equalization method and system of the present disclosure, the weight setting program is performed multiple times for adjusting the plurality of bit values (including the plurality of even bits and the plurality of odd bits) multiple times. As a result, a probability that each of the plurality of bit values of the input data is adjusted to be equal to the first weight value such as “1” is approximately equal to an average probability value.

If the odd and even bit weight equalization method and system of the present disclosure are applied for controlling the plurality of components, the plurality of bit values of the input data may respectively correspond to the plurality of components. A probability of turning on or using each of the plurality of components is approximately equal to a probability of turning on or using any other of the plurality of components and is approximately equal to the average probability value.

Differences between the plurality of components are often caused by variations in manufacturing processes of the plurality of components. When signals are transmitted through the plurality of components, the signals are interfered with the differences between the plurality of components to cause errors in the signals respectively outputted by the plurality of components, resulting in poor performance of the plurality of components. However, by using the odd and even bit weight equalization method and system of the present disclosure, the probabilities that the plurality of components are turned on or used are controlled to be approximately equal to each other, such that the errors in the signals respectively outputted by the components are averaged. Therefore, by using the odd and even bit weight equalization method and system of the present disclosure, the performance of the plurality of components is improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart diagram depicting processes of setting weight values of a plurality of even bits of input data in an odd and even bit weight equalization method according to an embodiment of the present disclosure;

FIG. 2 is a flowchart diagram depicting processes of setting weight values of a plurality of odd bits of the input data in the odd and even bit weight equalization method according to the embodiment of the present disclosure;

FIG. 3 is a flowchart diagram depicting processes of initially setting each of a plurality of bit values of the input data to be equal to a second weight value in the odd and even bit weight equalization method according to the embodiment of the present disclosure;

FIG. 4 is a flowchart diagram depicting processes of controlling components according to the weight values of the plurality of even and odd bits of the input data in the odd and even bit weight equalization method according to the embodiment of the present disclosure;

FIG. 5 is a flowchart diagram depicting processes of setting an even number and an odd number in the odd and even bit weight equalization method according to the embodiment of the present disclosure;

FIG. 6 is a flowchart diagram depicting processes of initially setting an even initial bit in the odd and even bit weight equalization method according to the embodiment of the present disclosure;

FIG. 7 is a flowchart diagram depicting processes of initially setting an odd initial bit in the odd and even bit weight equalization method according to the embodiment of the present disclosure;

FIG. 8 is a flowchart diagram depicting processes of subsequently setting the even initial bit in the odd and even bit weight equalization method according to the embodiment of the present disclosure;

FIG. 9 is a flowchart diagram depicting processes of subsequently setting the odd initial bit in the odd and even bit weight equalization method according to the embodiment of the present disclosure;

FIG. 10 is a schematic diagram of weight values outputted when a weight setting program is performed on the input data by an odd and even bit weight equalization system using the odd and even bit weight equalization method according to the embodiment of the present disclosure;

FIG. 11 is a schematic diagram of weight values outputted when a weight setting program is performed on the input data by the odd and even bit weight equalization system using the odd and even bit weight equalization method according to the embodiment of the present disclosure;

FIG. 12 is a block diagram of the odd and even bit weight equalization system according to the embodiment of the present disclosure;

FIG. 13 is a block diagram of the odd and even bit weight equalization system according to the embodiment of the present disclosure;

FIG. 14 is a circuit diagram of an even bit shifting circuit and an even output stage circuit of the odd and even bit weight equalization system according to the embodiment of the present disclosure; and

FIG. 15 is a circuit diagram of an odd bit shifting circuit and an odd output stage circuit of the odd and even bit weight equalization system according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

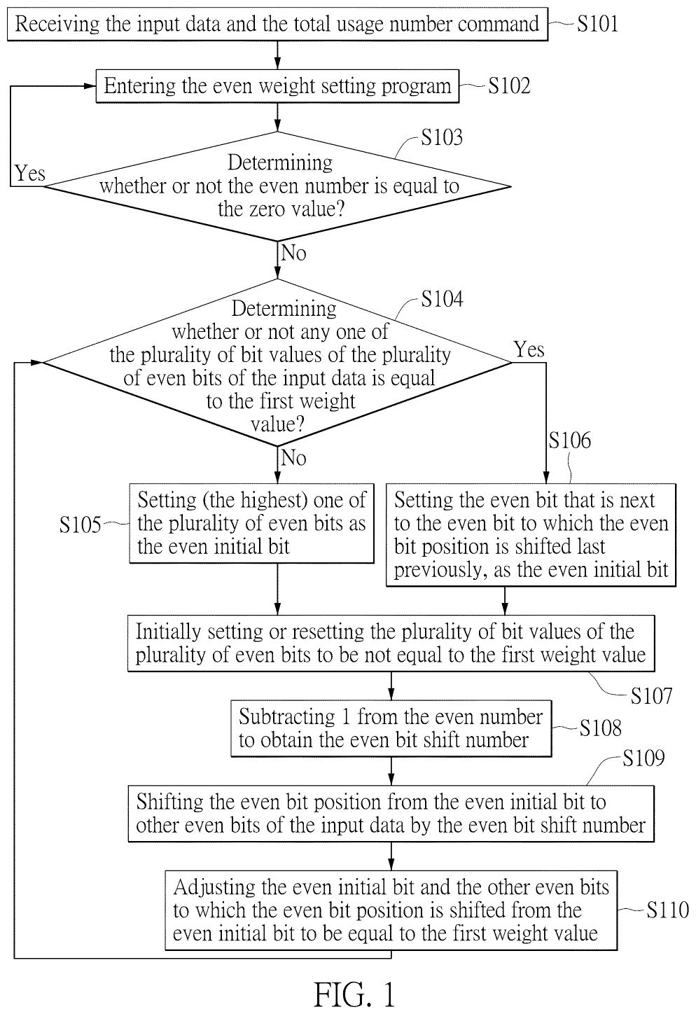

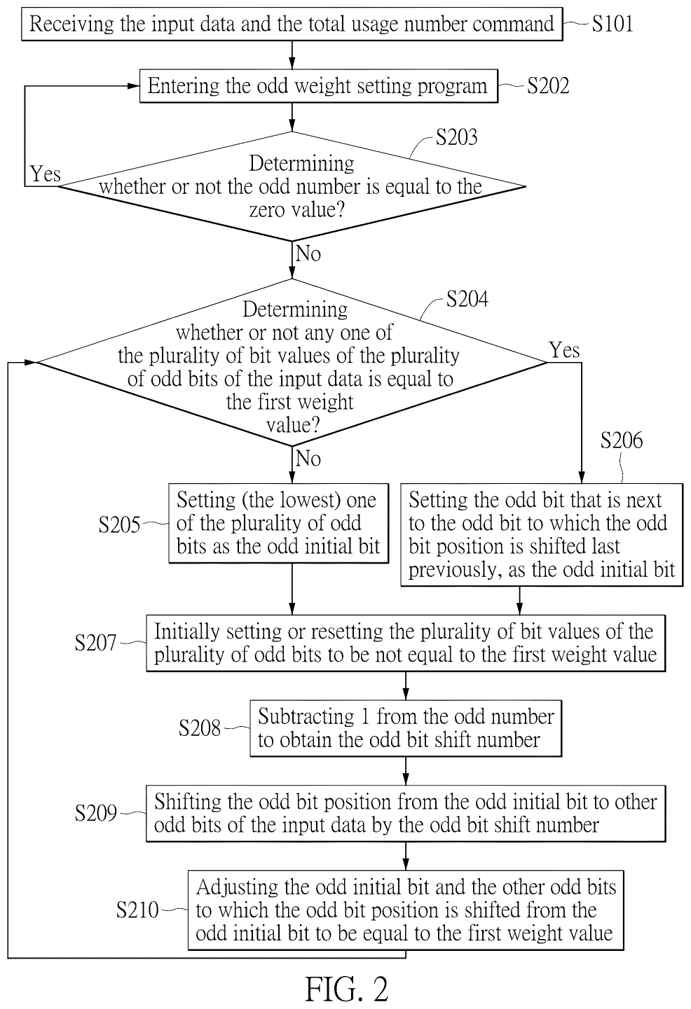

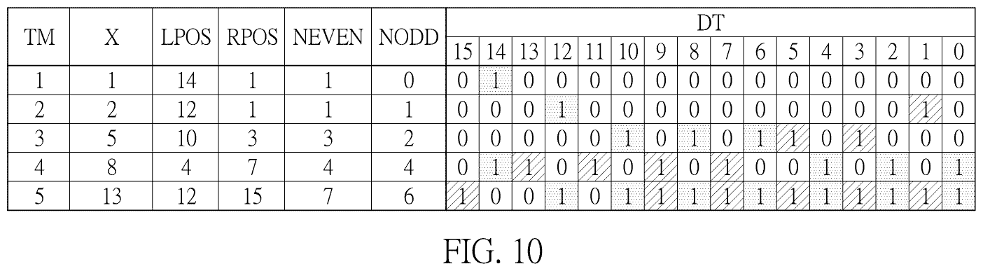

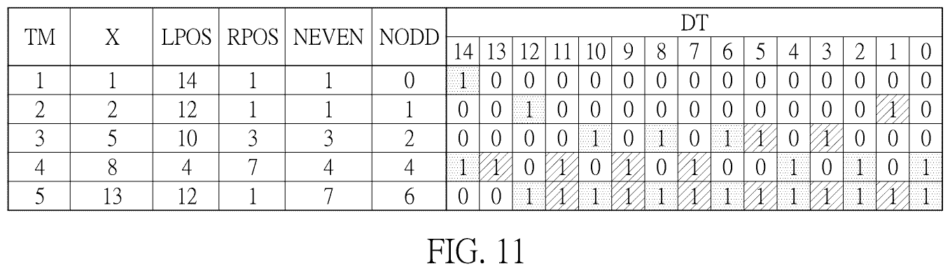

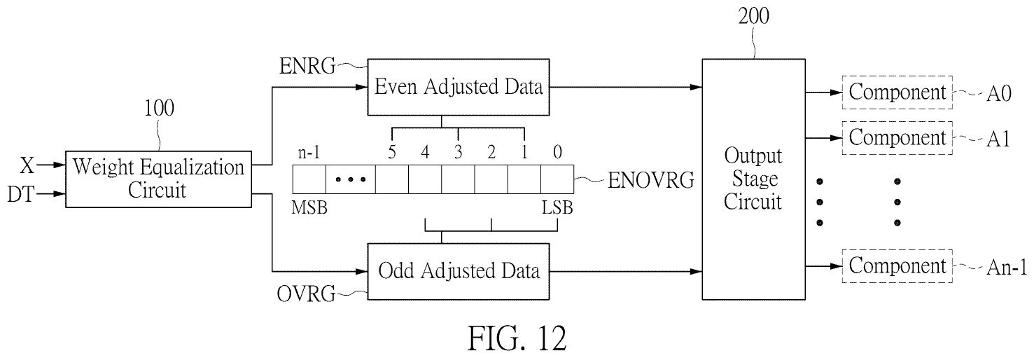

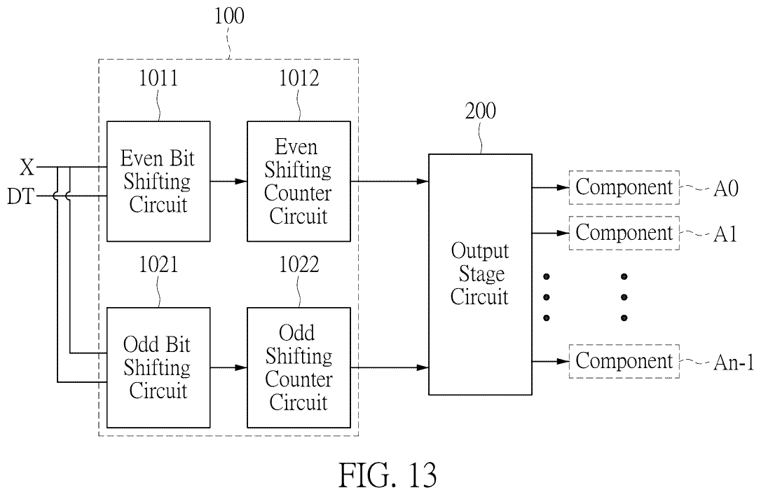

Reference is made to FIG. 1, FIG. 2 and FIG. 10 to FIG. 13, in which FIG. 1 is a flowchart diagram of processes of setting weight values of a plurality of even bits of input data in an odd and even bit weight equalization method according to an embodiment of the present disclosure, FIG. 2 is a flowchart diagram of processes of setting weight values of a plurality of odd bits of the input data in the odd and even bit weight equalization method according to the embodiment of the present disclosure, FIG. 10 and FIG. 11 are schematic diagrams of weight values outputted when a weight setting program is performed on the input data by an odd and even bit weight equalization system using the odd and even bit weight equalization method according to the embodiment of the present disclosure, and FIG. 12 and FIG. 13 are block diagrams of the odd and even bit weight equalization system according to the embodiment of the present disclosure.

The odd and even bit weight equalization system of the present disclosure includes a weight equalization circuit 100 as shown in FIG. 12. If necessary, the odd and even bit weight equalization system of the present disclosure may further include an output stage circuit 200 as shown in FIG. 12. The output stage circuit 200 is connected to the weight equalization circuit 100. The weight equalization circuit 100 includes a processor.

As shown in FIG. 13, the weight equalization circuit 100 may include an even bit shifting circuit 1011, an even shifting counter circuit 1012, an odd bit shifting circuit 1021 and an odd shifting counter circuit 1022. The even shifting counter circuit 1012 is connected to the even bit shifting circuit 1011 and the output stage circuit 200. Each of the even bit shifting circuit 1011, the even shifting counter circuit 1012, the odd bit shifting circuit 1021 and the odd shifting counter circuit 1022 may include one or more digital logic components, but the present disclosure is mot limited thereto. The odd shifting counter circuit 1022 is connected to the odd bit shifting circuit 1021 and the output stage circuit 200. The output stage circuit 200 is connected to a plurality of components A0 to An−1.

The odd and even bit weight equalization method of the present disclosure may be performed by the odd and even bit weight equalization system of the present disclosure as shown in FIG. 12 or FIG. 13. For convenience of explanation, only the odd and even bit weight equalization system shown in FIG. 13 is described for performing the odd and even bit weight equalization method of the present disclosure herein, but the present disclosure is not limited thereto.

It is worth noting that, the odd and even bit weight equalization method of the present disclosure includes processes S101 to S110 shown in FIG. 1 and processes S202 to S210 shown in FIG. 2.

In the odd and even bit weight equalization method of the present disclosure, the weight setting program is performed on input data DT multiple times. The weight setting program includes processes S101 to S110 shown in FIG. 1 and processes S202 to S210 shown in FIG. 2. The weight setting program performed each time is different from that performed next time. In the weight setting program performed each time, an odd weight setting program is performed once, and an even weight setting program is performed once. That is, in the odd and even bit weight equalization method of the present disclosure, the processes S101 to S110 of the odd weight setting program are performed multiple times, the processes S202 to S210 of the even weight setting program are performed multiple times.

In the process S101, the even bit shifting circuit 1011 of the weight equalization circuit 100 receives the input data DT from an external instructing circuit, and receives a plurality of total usage numbers X or a total usage number command indicating the plurality of total usage numbers X. The plurality of total usage numbers X are used respectively in the weight setting program performed multiple times. Each of the plurality of total usage numbers X includes an even number and an odd number.

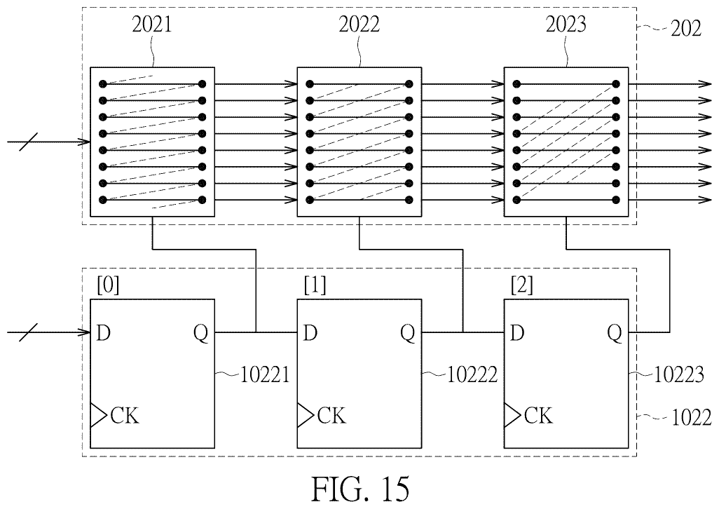

For example, the even bit shifting circuit 1011 of the weight equalization circuit 100 receives the input data DT that has 16 bits as shown in FIG. 10 or 15 bits as shown in FIG. 11, but the present disclosure is not limited thereto.

For example, the even bit shifting circuit 1011 of the weight equalization circuit 100 receives the total usage number command indicating the five total usage numbers X that are used in the weight setting program respectively performed for five times as shown in FIG. 10 and FIG. 11, but the present disclosure is not limited thereto. As shown in FIG. 10 and FIG. 11, the five total usage numbers X “1”, “2”, “5”, “8” and “13” are used respectively in the weight setting program performed for the first time, the second time, the third time, the fourth time and the fifth time. In the weight setting program performed each time, the number of the components that are turned on among the components A0 to An−1 may be equal to the total usage number X.

In the process S102, the even bit shifting circuit 1011 of the weight equalization circuit 100 enters the even weight setting program each time.

In the process S103, in the weight setting program performed each time, the even bit shifting circuit 1011 of the weight equalization circuit 100 sets the even number according to the total usage number X instructed by the total usage number command, and determines whether or not the even number is equal to a zero value. The even number set in the weight setting program performed each time may be different from that performed next time.

If the even number set in the even weight setting program included in the weight setting program performed each time is equal to the zero value, the even weight setting program is performed for the next time in the process S102 (or in practice, the even weight setting program is performed in the weight setting program performed each time). Conversely, if the even number set in the even weight setting program included in the weight setting program performed each time is not equal to the zero value, the process S104 is then performed.

For example, as shown in FIG. 10 and FIG. 11, even numbers NEVEN “1”, “1”, “3”, “4”, “7” each being not equal to 0 are used respectively in the weight setting program performed for five times, but the present disclosure is not limited thereto.

In the process S104, the even bit shifting circuit 1011 of the weight equalization circuit 100 determines whether or not any one of the plurality of bit values of the plurality of even bits (such as the zeroth, second, fourth, sixth, eighth, tenth, twelfth and fourteenth bits as shown in FIG. 10 and FIG. 11) of the input data DT is equal to a first weight value.

If the one of the plurality of bit values of the plurality of even bits of the input data DT is not equal to the first weight value, the process S105 is performed. Conversely, if the one of the plurality of bit values of the plurality of even bits of the input data DT is equal to the first weight value, the process S106 is performed.

In the process S105, the even bit shifting circuit 1011 of the weight equalization circuit 100 sets one (such as, but not limited to, a highest one) of the plurality of even bits of the input data DT as an even initial bit.

For example, as shown in FIG. 10 and FIG. 11, in the weight setting program performed for first time (TM=1), the even bit shifting circuit 1011 of the weight equalization circuit 100 sets the fourteenth bit among the plurality of bits of the input data DT that is the highest one of the plurality of even bits of the input data DT, as the even initial bit. An even bit number LPOS of the fourteenth bit among the plurality of bits of the input data DT is 14 (in the process S105).

In the process S106, the even bit shifting circuit 1011 of the weight equalization circuit 100 sets one (such as a next lower even bit) of the plurality of even bits that is next to the even bit to which an even bit position is last shifted previously, as the even initial bit.

For example, as shown in FIG. 10 and FIG. 11, in the weight setting program performed for second time (TM=2), the even bit shifting circuit 1011 of the weight equalization circuit 100 sets the twelfth bit that is a next lower even bit of the fourteenth bit among the plurality of bits of the input data DT, as the even initial bit. The even bit number LPOS of the twelfth bit among the plurality of bits of the input data DT is 12 (in the process S106).

In the process S107, in the even weight setting program performed each time, the even shifting counter circuit 1012 of the weight equalization circuit 100 adjusts each of the plurality of bit values of the plurality of even bits of the input data DT to be not equal to the first weight value.

That is, if one or more of the plurality of bit values of the plurality of even bits of the input data DT are adjusted to be equal to the first weight value in the weight setting program performed last previously, the one or more of the plurality of bit values of the plurality of even bits of the input data DT are reset to be not equal to the first weight value (in the process S107).

In the process S108, in the even weight setting program performed each time, the even bit shifting circuit 1011 of the weight equalization circuit 100 subtracts a value “1” from the even number to obtain a value as an even bit shift number.

In the process S109, in the even weight setting program performed each time, the even bit shifting circuit 1011 of the weight equalization circuit 100 shifts the even bit position from the even initial bit to one or more of the plurality of even bits by the even bit shift number.

In the process S110, in the even weight setting program performed each time, the even shifting counter circuit 1012 of the weight equalization circuit 100 adjusts the even initial bit and the even bits to which the even bit position is shifted to be equal to the first weight value.

For example, as shown in FIG. 10 and FIG. 11, when the weight setting program is performed for the first time (TM=1), an even number NEVEN is 1, and the even bit shifting circuit 1011 of the weight equalization circuit 100 subtracts a value “1” from the even number NEVEN “1” to obtain a value “0” as the even bit shift number. That is, the even bit position is not shifted in the weight setting program performed for the first time (TM=1). Therefore, in the weight setting program performed for the first time (TM=1), the even shifting counter circuit 1012 of the weight equalization circuit 100 only adjusts the fourteenth bit as the even initial bit among the plurality of bits of the input data DT to be equal to the first weight value such as “1”.

Then, as shown in FIG. 10 and FIG. 11, when the weight setting program is performed for the second time (TM=2), the even number NEVEN is 1, and the even bit shifting circuit 1011 of the weight equalization circuit 100 subtracts a value “1” from the even number NEVEN “1” to obtain a value “0” as the even bit shift number. That is, the even bit position is not shifted in the weight setting program performed for the second time (TM=2). Therefore, in the weight setting program performed for the second time (TM=2), the even shifting counter circuit 1012 of the weight equalization circuit 100 only adjusts the twelfth bit as the even initial bit among the plurality of bits of the input data DT to be equal to the first weight value such as “1”.

Then, as shown in FIG. 10 and FIG. 11, in the weight setting program performed for third time (TM=3), the even bit shifting circuit 1011 of the weight equalization circuit 100 sets the tenth bit among the plurality of bits of the input data DT, as the even initial bit. Among the plurality of bits of the input data DT, the tenth bit is a next lower bit of the twelfth bit to which the even bit position is last shifted previously in the weight setting program performed for the second time (TM=2). The even bit number LPOS of the tenth bit among the plurality of bits of the input data DT is 10.

As shown in FIG. 10 and FIG. 11, in the weight setting program performed for third time (TM=3), the even number NEVEN is 3, and the even bit shifting circuit 1011 of the weight equalization circuit 100 subtracts a value “1” from the even number NEVEN “3” to obtain a value “2” as the even bit shift number. Accordingly, the even bit shifting circuit 1011 of the weight equalization circuit 100 shifts the even bit position from the tenth bit that is set as the even initial bit sequentially to two lower even bits that are the eighth bit and the sixth bit among the plurality of bits of the input data DT.

As shown in FIG. 10 and FIG. 11, in the weight setting program performed for third time (TM=3), the even shifting counter circuit 1012 of the weight equalization circuit 100 adjusts the tenth bit that is set as the even initial bit, and the eighth bit and the sixth bit to which the even bit position is shifted from the tenth bit, to be equal to the first weight value such as “1”.

Then, as shown in FIG. 10 and FIG. 11, in the weight setting program performed the fourth time (TM=4), the even bit shifting circuit 1011 of the weight equalization circuit 100 sets the fourth bit among the plurality of bits of the input data DT as the even initial bit. Among the plurality of bits of the input data DT, the fourth bit is a next lower bit of the sixth bit to which the even bit position is last shifted previously in the weight setting program performed for third time (TM=3). The even bit number LPOS of the fourth bit as the even initial bit among the plurality of bits of the input data DT is 4.

As shown in FIG. 10 and FIG. 11, in the weight setting program performed for the fourth time (TM=4), the even number NEVEN is 4, and the even bit shifting circuit 1011 of the weight equalization circuit 100 subtracts a value “1” from the even number NEVEN “4” to obtain a value “3” as the even bit shift number. Accordingly, the even bit shifting circuit 1011 of the weight equalization circuit 100 shifts the even bit position from the fourth bit that is set as the even initial bit sequentially to two lower even bits that are the second bit and the zeroth bit among the plurality of bits of the input data DT.

As shown in FIG. 10 and FIG. 11, when the number of the even bits to which the even bit position is shifted is “2” is smaller than the even bit shift number “3”, and the even bit position is shifted to the zeroth bit that is a lowest one of the plurality of even bits of the input data DT, the even bit shifting circuit 1011 of the weight equalization circuit 100 shifts the even bit position from the zeroth bit to the fourteenth bit that is a highest one of the plurality of even bits of the input data DT.

As shown in FIG. 10 and FIG. 11, in the weight setting program performed for the fourth time (TM=4), the even shifting counter circuit 1012 of the weight equalization circuit 100 adjusts the fourth bit that is set as the even initial bit, and the second bit, the zeroth bit and the fourteenth bit to which the even bit position is shifted from the fourth bit, to be equal to the first weight value such as “1”.

Then, as shown in FIG. 10 and FIG. 11, in the weight setting program performed fifth time (TM=5), the even bit shifting circuit 1011 of the weight equalization circuit 100 sets the twelfth bit among the plurality of bits of the input data DT as the even initial bit. Among the plurality of bits of the input data DT, the twelfth bit is the next lower bit of the fourteenth bit to which the even bit position is last shifted previously in the weight setting program performed for the fourth time (TM=4). The even bit number LPOS of the twelfth bit that is set as the even initial bit among the plurality of bits of the input data DT is 12.

As shown in FIG. 10 and FIG. 11, in the weight setting program performed for the fifth time (TM=5), the even number NEVEN is 7, the even bit shifting circuit 1011 of the weight equalization circuit 100 subtracts a value “1” from the even number NEVEN “7” to obtain a value “6” as the even bit shift number. Accordingly, the even bit shifting circuit 1011 of the weight equalization circuit 100 shifts the even bit position from the twelfth that is set as the even initial bit sequentially to six lower even bits that are the tenth bit, the eighth bit, the sixth bit, the fourth bit, the second bit and the zeroth bit among the plurality of bits of the input data DT.

As shown in FIG. 10 and FIG. 11, after the weight setting program is performed for five times (TM=1 to 5), each of the plurality of bit values of the plurality of even bits of the input data DT is adjusted to be equal to the first weight value such as “1” twice. Accordingly, a probability that each of the plurality of bit values of the plurality of even bits of the input data DT is adjusted to be equal to the first weight value is equal to a probability that any other of the plurality of bit values of the plurality of even bits of the input data DT is adjusted to be equal to the first weight value.

As described above, the highest one of the plurality of even bits of the input data DT is set as the even initial bit first, and the even bit position is shifted from the highest one of the plurality of even bits of the input data DT to lower ones of the plurality of even bits of the input data DT. When the even bit position is shifted to the lowest one of the plurality of even bits of the input data DT, the even bit position is then shifted to the highest one of the plurality of even bits of the input data DT, and then is shifted to the lower ones of the plurality of even bits of the input data DT again and again. In practice, any one of the plurality of even bits of the input data DT may be set as the even initial bit first according to actual requirements, and a direction in which the even bit position is shifted from the even initial bit to other lower even bits among the plurality of even bits of the input data DT may be adjusted.

After the process S101 is performed, the weight setting program is performed multiple times. The weight setting program performed each time includes the processes S102 to S110 of the even weight setting program and the processes S202 to S210 of the odd weight setting program. The even weight setting program and the odd weight setting program may be synchronously performed. Alternatively, the odd weight setting program may be performed after or before the even weight setting program.

In the process S202, the odd bit shifting circuit 1021 of the weight equalization circuit 100 enters the odd weight setting program each time.

In the process S203, in the weight setting program performed each time, the odd bit shifting circuit 1021 of the weight equalization circuit 100 sets the odd number according to the total usage number X instructed by the total usage number command, and determines whether or not the odd number is equal to a zero value. The odd number set in the weight setting program performed each time may be different from that performed next time.

If the odd number set in the odd weight setting program included in the weight setting program performed each time is equal to the zero value, the odd weight setting program is performed for the next time in the process S202 (or in practice, the odd weight setting program is performed in the weight setting program performed each time). Conversely, if the odd number set in the odd weight setting program included in the weight setting program performed each time is not equal to the zero value, the process S204 is performed.

In the process S204, the odd bit shifting circuit 1021 of the weight equalization circuit 100 determines whether or not any one of the plurality of bit values of the plurality of odd bits of the input data DT is equal to the first weight value.

If the one of the plurality of bit values of the plurality of odd bits of the input data DT is not equal to the first weight value, the process S205 is performed. Conversely, if the one of the plurality of bit values of the plurality of odd bits of the input data DT is equal to the first weight value, the process S206 is performed.

In the process S205, the odd bit shifting circuit 1021 of the weight equalization circuit 100 sets one (such as, but not limited to a lowest one) of the plurality of odd bits of the input data DT as an odd initial bit.

In the process S206, the odd bit shifting circuit 1021 of the weight equalization circuit 100 sets one of the plurality of odd bits that is next to the odd bit to which an odd bit position is last shifted previously, as the odd initial bit.

In the process S207, the odd shifting counter circuit 1022 of the weight equalization circuit 100 adjusts each of the plurality of bit values of the plurality of odd bits of the input data DT to be not equal to the first weight value.

That is, if one or more of the plurality of bit values of the plurality of odd bits of the input data DT are adjusted to be equal to the first weight value in the weight setting program performed last previously, the one or more of the plurality of bit values of the plurality of odd bits of the input data DT are reset before the plurality of bit values of the plurality of odd bits of the input data DT is set in the weight setting program performed each time (in the process S207).

In the process S208, in the odd weight setting program performed each time, the odd shifting counter circuit 1022 of the weight equalization circuit 100 subtracts a value “1” from the odd number to obtain a value as an odd bit shift number.

In the process S209, in the odd weight setting program performed each time, the odd shifting counter circuit 1022 of the weight equalization circuit 100 shifts the odd bit position from the odd initial bit to one or more of the plurality of odd bits by the odd bit shift number.

In the process S210, in the odd weight setting program performed each time, the odd shifting counter circuit 1022 of the weight equalization circuit 100 adjusts the odd initial bit and the odd bits to which the odd bit position is shifted to be equal to the first weight value.

For example, as shown in FIG. 10 and FIG. 11, in the weight setting program performed for the first time (TM=1), an odd number NODD is 0, and the odd bit shifting circuit 1021 of the weight equalization circuit 100 sets the lowest one of the plurality of odd bits of the input data DT that is a first one of the plurality of bits of the input data DT, as the odd initial bit. An odd bit number RPOS of the first one of the plurality of bits of the input data DT is 1.

Then, in the weight setting program performed for the second time (TM=2), the odd number NODD is 1, and the odd bit shifting circuit 1021 of the weight equalization circuit 100 subtracts a value “1” from the odd number NODD “1” to obtain a value “0” as the odd bit shift number. That is, the odd bit position is not shifted in the weight setting program performed for the second time (TM=2). Therefore, in the weight setting program performed for the second time (TM=2), the odd shifting counter circuit 1022 of the weight equalization circuit 100 only adjusts the first one of the plurality of bits of the input data DT as the odd initial bit to be equal to the first weight value such as “1”.

Then, as shown in FIG. 10 and FIG. 11, in the weight setting program performed for third time (TM=3), the odd bit shifting circuit 1021 of the weight equalization circuit 100 sets a third bit among the plurality of bits of the input data DT, as the odd initial bit. Among the plurality of bits of the input data DT, the third bit is a next higher bit of a first bit to which the odd bit position is last shifted previously in the weight setting program performed for the second time (TM=2). The odd bit number RPOS of the third bit as the odd initial bit among the plurality of bits of the input data DT is 3.

As shown in FIG. 10 and FIG. 11, in the weight setting program performed for third time (TM=3), the odd number NODD is 2, and the odd bit shifting circuit 1021 of the weight equalization circuit 100 subtracts a value “1” from the odd number NODD “2” to obtain a value “1” as the odd bit shift number. Accordingly, the odd bit shifting circuit 1021 of the weight equalization circuit 100 shifts the odd bit position from the third bit that is set as the odd initial bit to a next higher odd bit that is a fifth bit among the plurality of bits of the input data DT.

As shown in FIG. 10 and FIG. 11, in the weight setting program performed for third time (TM=3), the odd shifting counter circuit 1022 of the weight equalization circuit 100 adjusts the third bit that is set as the odd initial bit and the fifth bit to which the odd bit position is shifted from the third bit to be equal to the first weight value such as “1”.

Then, as shown in FIG. 10 and FIG. 11, in the weight setting program performed for the fourth time (TM=4), the odd bit shifting circuit 1021 of the weight equalization circuit 100 sets a seventh bit among the plurality of bits of the input data DT as the odd initial bit. Among the plurality of bits of the input data DT, the seventh bit is a next higher odd bit of the fifth bit to which the odd bit position is last shifted previously in the weight setting program performed for third time (TM=3). The odd bit number RPOS of the seventh bit as the odd initial bit among the plurality of bits of the input data DT is 7.

In the weight setting program performed for the fourth time (TM=4), the odd number NODD is 4, and the odd bit shifting circuit 1021 of the weight equalization circuit 100 subtracts a value “1” from the odd number NODD “4” to obtain a value “3” as the odd bit shift number. Accordingly, the odd bit shifting circuit 1021 of the weight equalization circuit 100 shifts the odd bit position from the seventh bit that is set as the odd initial bit sequentially to three higher odd bits that are a ninth bit, an eleventh bit and a thirteenth bit among the plurality of bits of the input data DT.

As shown in FIG. 10 and FIG. 11, in the weight setting program performed for the fourth time (TM=4), the odd shifting counter circuit 1022 of the weight equalization circuit 100 adjusts the seventh bit that is set as the odd initial bit, and the ninth bit, the eleventh bit and the thirteenth bit to which the odd bit position is shifted from the seventh bit, to be equal to the first weight value such as “1”.

Then, as shown in FIG. 10, in the weight setting program performed for the fourth time (TM=5), the odd bit shifting circuit 1021 of the weight equalization circuit 100 sets a fifteenth bit among the plurality of bits of the input data DT as the odd initial bit. Among the plurality of bits of the input data DT, the fifteenth bit is a next higher bit of the thirteenth bit to which the odd bit position is last shifted previously in the weight setting program performed for the fourth time (TM=4). The odd bit number RPOS of the fifteenth bit among the plurality of bits of the input data DT is 15.

As shown in FIG. 10, in the weight setting program performed for the fourth time (TM=5), the odd number NODD is 6, and the odd bit shifting circuit 1021 of the weight equalization circuit 100 subtracts a value “1” from the odd number NODD “6” to obtain a value “5” as the odd bit shift number.

As shown in FIG. 10, when the odd bit position is shifted to the highest one such as the fifteenth one of the plurality of odd bits of the input data DT, the odd bit shifting circuit 1021 of the weight equalization circuit 100 shifts the odd bit position from the highest one of the plurality of odd bits of the input data DT that is the fifteenth one of the plurality of bits of the input data DT to the lowest one of the plurality of odd bits of the input data DT that is the first one of the plurality of bits of the input data DT, and then sequentially to the third bit, the fifth bit, seventh bit and the ninth bit among the plurality of bits of the input data DT.

Then, as shown in FIG. 10, in the weight setting program performed for the fourth time (TM=5), the odd bit shifting circuit 1021 of the weight equalization circuit 100 adjusts the fifteenth bit that is set as the odd initial bit, and the first bit, the third bit, the fifth bit, the seventh bit and the ninth bit to which the odd bit position is shifted from the fifteenth bit, to be equal to the first weight value such as “1”.

As shown in FIG. 11, in the weight setting program performed for the fourth time (TM=4), the odd bit position is shifted to the thirteenth one that is the highest one of the plurality of odd bits of the input data DT. Therefore, in the weight setting program performed for the fifth time (TM=5), the odd bit shifting circuit 1021 of the weight equalization circuit 100 sets the lowest one of the plurality of odd bits of the input data DT that is the first one of the plurality of bits of the input data DT as the odd initial bit again. In the weight setting program performed for the fifth time (TM=5), the odd number NODD is six, and thus the odd bit shifting circuit 1021 of the weight equalization circuit 100 shifts the odd bit position from the first one of the plurality of bits of the input data DT sequentially to six odd bits that are the third bit, the fifth bit, the seventh bit, the ninth bit and the eleventh bit among the plurality of bits of the input data DT.

As shown in FIG. 11, in the weight setting program performed for the fourth time (TM=5), the odd bit shifting circuit 1021 of the weight equalization circuit 100 adjusts the first bit is set as the odd initial bit, and the third bit, the fifth bit, the seventh bit, the ninth bit and the eleventh bit to which the odd bit position is shifted from the first bit, to be equal to the first weight value such as “1”.

As shown in FIG. 10 and FIG. 11, in the weight setting program performed five time (TM=1 to 5), each of the plurality of bit values of the plurality of odd bits of the input data DT is adjusted to be equal to the first weight value such as “1” once or twice.

As described above, after the weight setting program of the odd and even bit weight equalization method of the present disclosure is performed multiple times, the plurality of bit values (including the plurality of bit values of the plurality of even bits and the plurality of odd bits) of the input data DT are adjusted multiple times. The probability that each of the plurality of bit values of the input data DT is adjusted to be equal to the first weight value such as “1” is approximately equal to an average probability value.

As described above, the lowest one of the plurality of odd bits of the input data DT is set as the odd initial bit first, and the odd bit position is shifted from the lowest one of the plurality of odd bits of the input data DT to other higher odd ones of the plurality of odd bits of the input data DT. When the odd bit position is shifted to the highest one of the plurality of odd bits of the input data DT, the odd bit position is then shifted to the lowest one of the plurality of odd bits of the input data DT, and then is shifted to other higher odd ones of the plurality of odd bits of the input data DT again and again. In practice, any one of the plurality of odd bits of the input data DT may be set as the odd initial bit according to actual requirements, and a direction in which the odd bit position is shifted from the odd initial bit to other higher odd bits among the plurality of odd bits of the input data DT may be adjusted.

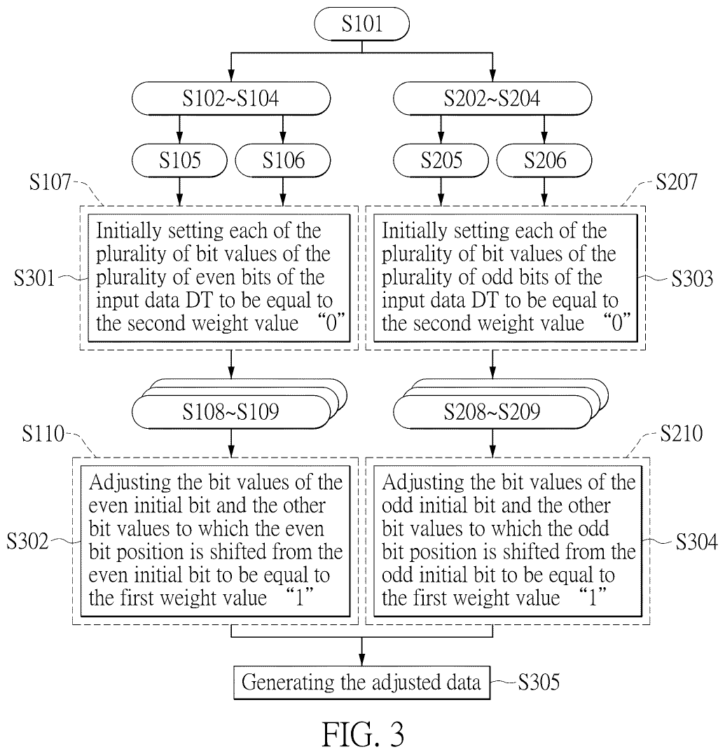

Reference is made to FIG. 3, FIG. 12 and FIG. 13, in which FIG. 3 is a flowchart diagram of processes of initially setting each of a plurality of bit values of the input data to be equal to a second weight value in the odd and even bit weight equalization method according to the embodiment of the present disclosure, and FIG. 12 and FIG. 13 are block diagrams of the odd and even bit weight equalization system according to the embodiment of the present disclosure.

The odd and even bit weight equalization system of the present disclosure may further include processes S301 to S305 as shown in FIG. 3.

In the weight setting program performed each time, before any one or more of the plurality of bit values of the plurality of even bits of the input data DT is adjusted to be equal to the first weight value such as “1” (in the processes S108 to S110), the even shifting counter circuit 1012 of the weight equalization circuit 100 may initially set or reset each of the plurality of bit values of the plurality of even bits of the input data DT to be equal to a second weight value such as “0” (in the process S301).

Further, when the even initial bit and the one or more bit values to which the even bit position is shifted from the even initial bit of the input data DT are adjusted to be equal to the second weight value such as “0” (in the process S301), the even shifting counter circuit 1012 of the weight equalization circuit 100 sets the first weight value such as “1”, and adjusts the bit value of the even initial bit and the one or more bit values to which the even bit position is shifted from the even initial bit to be equal to the first weight value such a “1” from the second weight value “0” (in the process S302).

On the other hand, in the weight setting program performed each time, before any one or more of the plurality of bit values of the plurality of odd bits of the input data DT is adjusted to be equal to the first weight value such as “1” (in the processes S208 to S210), the odd shifting counter circuit 1022 of the weight equalization circuit 100 may initially set or reset each of the plurality of bit values of the plurality of odd bits of the input data DT to be equal to the second weight value such as “0” (in the process S303).

Further, when the odd initial bit and the one or more bit values to which the odd bit position is shifted from the odd initial bit of the input data DT are adjusted to be equal to the second weight value such as “0” (in the process S303), the odd shifting counter circuit 1022 of the weight equalization circuit 100 sets the first weight value such as “1”, and adjusts the bit values of the odd initial bit and the one or more bit values to which the odd bit position is shifted from the odd initial bit to be equal to the first weight value such as “1” from the second weight value such as “0” (in the process S304).

As shown in FIG. 12, the weight equalization circuit 100 may use the input data DT as adjusted data ENOVRG (in the process S305). The adjusted data ENOVRG may include a plurality of pieces of sub-adjusted data that are respectively generated in the weight setting program performed multiple times, and the number of the plurality of bits of each of the plurality of pieces of sub-adjusted data is equal to the number of the plurality of bits of the input data DT. The adjusted data ENOVRG that is generated in the weight setting program performed each time includes an even adjusted data ENRG and an odd adjusted data OVRG.

The even shifting counter circuit 1012 of the weight equalization circuit 100 as shown in FIG. 13 may set the plurality of bit values of the plurality of even bits of the adjusted data ENOVRG that is the adjusted input data DT as a plurality of bit values of a plurality of even bits of an even adjusted data, and may set the plurality of bit values of the plurality of odd bits of the adjusted data ENOVRG as a plurality of bit values of a plurality of odd bits of an odd adjusted data (in the process S305).

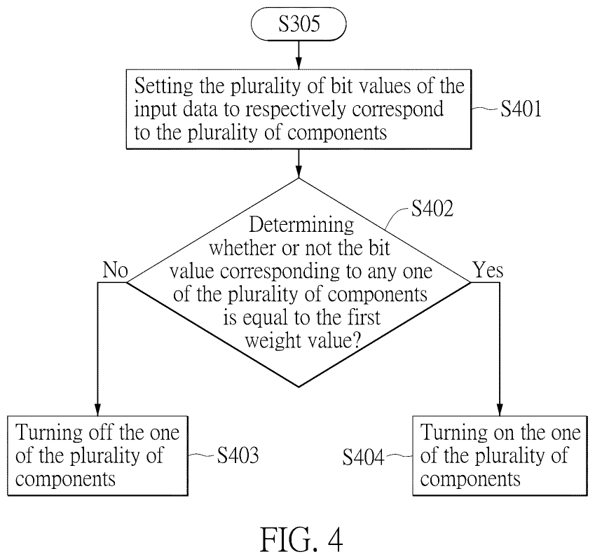

Reference is made to FIG. 4 and FIG. 13, in which FIG. 4 is a flowchart diagram of processes of controlling components according to the weight values of the plurality of even and odd bits of the input data in the odd and even bit weight equalization method according to the embodiment of the present disclosure, and FIG. 13 is a block diagram of the odd and even bit weight equalization system according to the embodiment of the present disclosure.

The odd and even bit weight equalization method of the present disclosure may further include processes S401 to S404 as shown in FIG. 4. After the adjusted data ENOVRG (including the even adjusted data ENRG and the odd adjusted data OVRG) is generated in the process S305, the processes S401 to S404 are performed.

In the process S401, the weight equalization circuit 100 as shown in FIG. 12 sets a with the plurality of bit serial numbers “0” to “(n−1)” respectively of the plurality of bit values of the input data DT to respectively correspond to the plurality of components A0 to An−1 (according to an external component control command from the external instructing circuit), wherein “n” in the bit number “(n−1)” is equal to the number of the plurality of bits of the input data DT. Each of the plurality of components A0 to An−1 may be any electronic component. The weight equalization circuit 100 outputs the plurality of bit values of the adjusted data ENOVRG (that is the adjusted input data DT) respectively to the corresponding components A0 to An−1.

In detail, the even bit shifting circuit 1011 of the weight equalization circuit 100 as shown in FIG. 13 sets the plurality of even bits of the input data DT respectively correspond to some of the plurality of components A0 to An−1. For example, the even bits numbered respectively with the bit serial numbers “0”, “2”, “4”, “6”, “8”, “10”, “12”, “14” as shown in FIG. 10 and FIG. 11 respectively correspond to the plurality of components A0, A2, A4, A6, A8, A10, A12, A14 as shown in FIG. 13, but the present disclosure is not limited thereto. The weight equalization circuit 100 outputs the plurality of bit values of the plurality of even bits of the adjusted data ENOVRG (that is the adjusted input data DT) respectively to corresponding ones of the components A0 to An−1.

The odd bit shifting circuit 1021 of the weight equalization circuit 100 as shown in FIG. 13 sets the plurality of odd bits of the input data DT respectively correspond to some of the plurality of components A0 to An−1. For example, the odd bits numbered respectively with the bit serial numbers “1”, “3”, “5”, “7”, “9”, “11”, “13”, “15” as shown in FIG. 11 respectively correspond to the plurality of components A1, A3, A5, A7, A9, A11, A13, A15 as shown in FIG. 13, but the present disclosure is not limited thereto. The weight equalization circuit 100 outputs the plurality of bit values of the plurality of odd bits of the adjusted data ENOVRG (that is the adjusted input data DT) respectively to corresponding ones of the components A0 to An−1.

In the process S402, each of the plurality of components A0 to An−1 determines whether or not the bit value from the weight equalization circuit 100 is equal to the first weight value.

In the process S403, if the bit value received by any one of the plurality of components A0 to An−1 from the weight equalization circuit 100 is not equal to the first weight value (and is equal to the second weight value), the one of the plurality of components A0 to An−1 is turned off by the received bit value that is not equal to the first weight value (and is equal to the second weight value).

In the process S404, if the bit value received by any one of the plurality of components A0 to An−1 from the weight equalization circuit 100 is equal to the first weight value, the one of the plurality of components A0 to An−1 is turned on by the received bit value being equal to the first weight value.

According to above, in the odd and even bit weight equalization method of the present disclosure, the plurality of bit values of the adjusted data ENOVRG that are generated in the weight setting program performed multiple times may be outputted respectively to the plurality of components A0 to An−1 for controlling the plurality of components A0 to An−1. The plurality of components A0 to An−1 are turned on or used almost averagely in turn. A probability of turning on or using each of the plurality of components A0 to An−1 is fully or approximately equal to a probability of turning on or using each other of the plurality of components A0 to An−1.

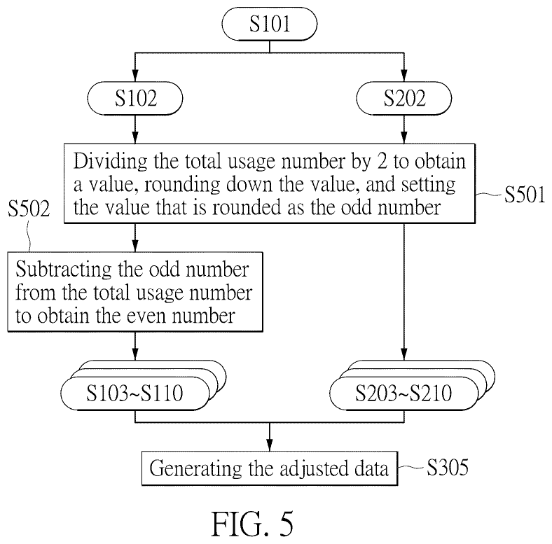

Reference is made to FIG. 5 and FIG. 13, in which FIG. 5 is a flowchart diagram of processes of setting an even number and an odd number in the odd and even bit weight equalization method according to the embodiment of the present disclosure, and FIG. 13 is a block diagram of the odd and even bit weight equalization system according to the embodiment of the present disclosure.

The odd and even bit weight equalization method of the present disclosure may further include processes S501 to S502 as shown in FIG. 5.

After the weight equalization circuit 100 obtains the total usage number X from the total usage number command for the weight setting program performed each time (the process S101), the weight equalization circuit 100 enters the weight setting program including the even weight setting program (the process S102) and the odd weight setting program (the process S202).

Then, the odd bit shifting circuit 1021 of the weight equalization circuit 100 divides the total usage number X by a value “2” to obtain a arithmetic value, rounding down the arithmetic value, and sets the rounded arithmetic value as the odd number (the process S501), which is represented by the following equation:

$$NODD = I N T ( X / 2 ) ,$$

wherein NODD represents the odd number, and X represents the total usage number (i.e., the number of the components being turned on among the components A0 to An−1).

The even bit shifting circuit 1011 of the weight equalization circuit 100 may be connected to the odd bit shifting circuit 1021, and may obtain the odd number from the odd bit shifting circuit 1021 In the weight setting program performed each time, the even bit shifting circuit 1011 subtracts the odd number NODD from the total usage number X to obtain the even number, which is represented by the following equation:

$$NEVEN = X - NODD ,$$

wherein NEVEN represents the even number, NODD represents the odd number, and X represents the total usage number (i.e., the number of the components being turned on among the components A0 to An−1).

After the process S501 is performed, the processes S203 to S210 of the odd weight setting program are performed. After the processes S501 to S502 are sequentially performed, the processes S103 to S110 of the even weight setting program are sequentially performed.

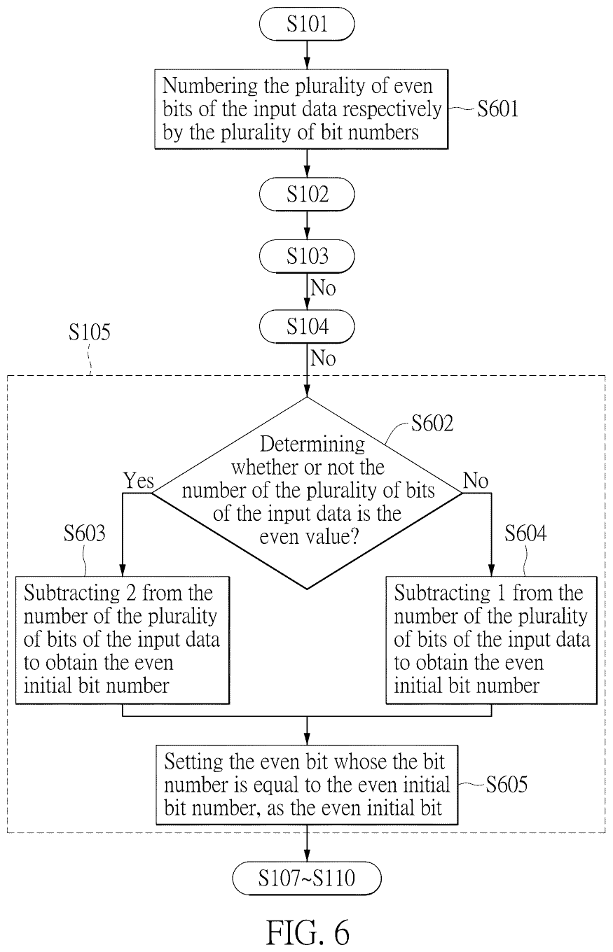

Reference is made to FIG. 6, FIG. 10, FIG. 11 and FIG. 13, in which FIG. 6 is a flowchart diagram of processes of initially setting an even initial bit in the odd and even bit weight equalization method according to the embodiment of the present disclosure, FIG. 10 and FIG. 11 are schematic diagrams of weight values outputted when a weight setting program is performed on the input data by the odd and even bit weight equalization method and the odd and even bit weight equalization system according to the embodiment of the present disclosure, and FIG. 13 is a block diagram of the odd and even bit weight equalization system according to the embodiment of the present disclosure.

The odd and even bit weight equalization method of the present disclosure may further include processes S601 to S605 as shown in FIG. 6.

After the even bit shifting circuit 1011 of the weight equalization circuit 100 receives the input data DT and the total usage number command from the external instructing circuit in the process S101, the process S601 is performed.

In the process S601, the even bit shifting circuit 1011 of the weight equalization circuit 100 numbers the plurality of even bits of the input data DT sequentially from a lowest bit LSB to a highest bit MSB with the plurality of bit serial numbers that are even values such as 0, 2, 4, 6, 8, 10, 12, 14 as shown in FIG. 10 and FIG. 11 (in the process S601).

After the process S601 is performed, the processes S102 to S104 are sequentially performed.

When each of the plurality of bit values of the plurality of even bits of the input data DT is determined not to be equal to the first weight value in the process S104, the processes S602 to S605 included in the process S105 as shown in FIG. 6 are performed for setting the highest one of the plurality of even bits of the input data DT as the even initial bit.

In the process S602, the even bit shifting circuit 1011 of the weight equalization circuit 100 determines whether or not the number of the plurality of bits of the input data DT is an even value.

If the number of the plurality of bits of the input data DT is the even value, the process S603 is performed. Conversely, if the number of the plurality of bits of the input data DT is not the even value (and is an odd value), the process S604 is performed.

In the process S603, the even bit shifting circuit 1011 of the weight equalization circuit 100 subtracts a value “2” from the number of the plurality of bits of the input data DT to obtain a value as an even initial bit number, which is represented by the following equation:

$$LPOS = N - 2 ,$$

wherein LPOS represents the even initial bit number that is the bit number of the even initial bit, and N represents the number of the plurality of bits of the input data DT.

For example, as shown in FIG. 10, in the weight setting program performed for the first time (TM=1), the number of the plurality of bits of the input data DT is 16 that is the even value. The sixteen bits are numbered respectively with bit serial numbers “0” to “15”. The even bit shifting circuit 1011 of the weight equalization circuit 100 subtracts a value “2” from the number of the plurality of bits of the input data DT “16” to obtain a value “14” as the even initial bit number.

In the process S604, the even bit shifting circuit 1011 of the weight equalization circuit 100 subtracts a value “1” from the number of the plurality of bits of the input data DT as the even initial bit number, which is represented by the following equation:

$$LPOS = N - 1 ,$$

wherein LPOS represents the even initial bit number that is the bit number of the even initial bit, and N represents the number of the plurality of bits of the input data DT.

For example, as shown in FIG. 11, in the weight setting program performed for the first time (TM=1), the number of the plurality of bits of the input data DT is 15 that is an even value. The fifteen bits are numbered respectively with bit serial numbers “0” to “14”. The even bit shifting circuit 1011 of the weight equalization circuit 100 subtracts a value “1” from the number of the plurality of bits of the input data DT “15” to obtain a value “14” as the even initial bit number.

In the process S605, the even bit shifting circuit 1011 of the weight equalization circuit 100 sets the even bit whose bit number is equal to the even initial bit number as the even initial bit.

After the process S605 is performed, the processes S107 to S110 are sequentially performed.

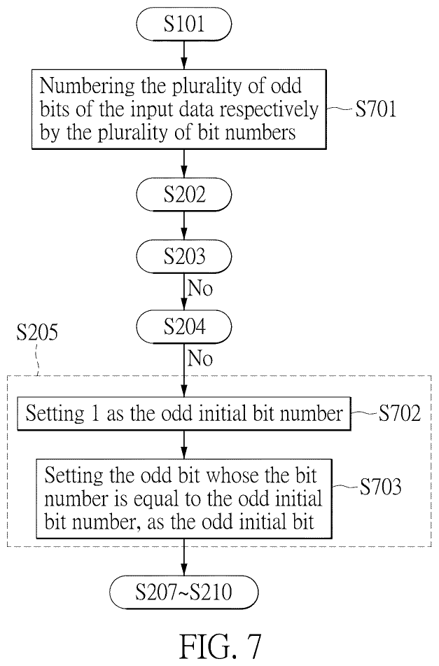

Reference is made to FIG. 7, FIG. 10, FIG. 11 and FIG. 13, in which FIG. 7 is a flowchart diagram of processes of initially setting an odd initial bit in the odd and even bit weight equalization method according to the embodiment of the present disclosure, FIG. 10 and FIG. 11 are schematic diagrams of weight values outputted when a weight setting program is performed on the input data by the odd and even bit weight equalization method and the odd and even bit weight equalization system according to the embodiment of the present disclosure, and FIG. 13 is a block diagram of the odd and even bit weight equalization system according to the embodiment of the present disclosure.

The odd and even bit weight equalization method of the present disclosure may further include processes S701 to S703 as shown in FIG. 7.

In the process S701, the odd bit shifting circuit 1021 of the weight equalization circuit 100 numbers the plurality of odd bits of the input data DT sequentially from the lowest bit LSB to the highest bit MSB with the plurality of bit serial numbers that are odd values such as 1, 3, 5, 7, 9, 11, 13, 15 as shown in FIG. 10 or 1, 3, 5, 7, 9, 11, 13 as shown in FIG. 11.

After the process S701 is performed, the processes S202 to S204 are sequentially performed.

When each of the plurality of bit values of the plurality of odd bits of the input data DT is determined not to be equal to the first weight value in the process S104, the processes S702 to S703 included in the process S205 as shown in FIG. 7 are performed for setting the lowest one of the plurality of odd bits of the input data DT as the odd initial bit.

In the process S702, the odd bit shifting circuit 1021 of the weight equalization circuit 100 sets the odd initial bit number to be equal to “1”.

In the process S703, the odd bit shifting circuit 1021 of the weight equalization circuit 100 sets the odd bit whose the odd initial bit number is equal to the odd initial bit number “1” as the odd initial bit.

For example, as shown in FIG. 10 and FIG. 11, the odd number NODD is “1” instead of “0” in the weight setting program performed for the second time (TM=2) (in the process S203), and each of the plurality of bit values of the plurality of odd bits of the input data DT is not equal to the first weight value such as “1” in the weight setting program performed for the first time (TM=1) (in the process S204). Under this condition, the odd bit whose the odd initial bit number is equal to the odd initial bit number “1” is set as the odd initial bit. The odd bit number RPOS of this odd initial bit is 1.

After the process S701 is performed, the processes S207 to S210 described above are sequentially performed.

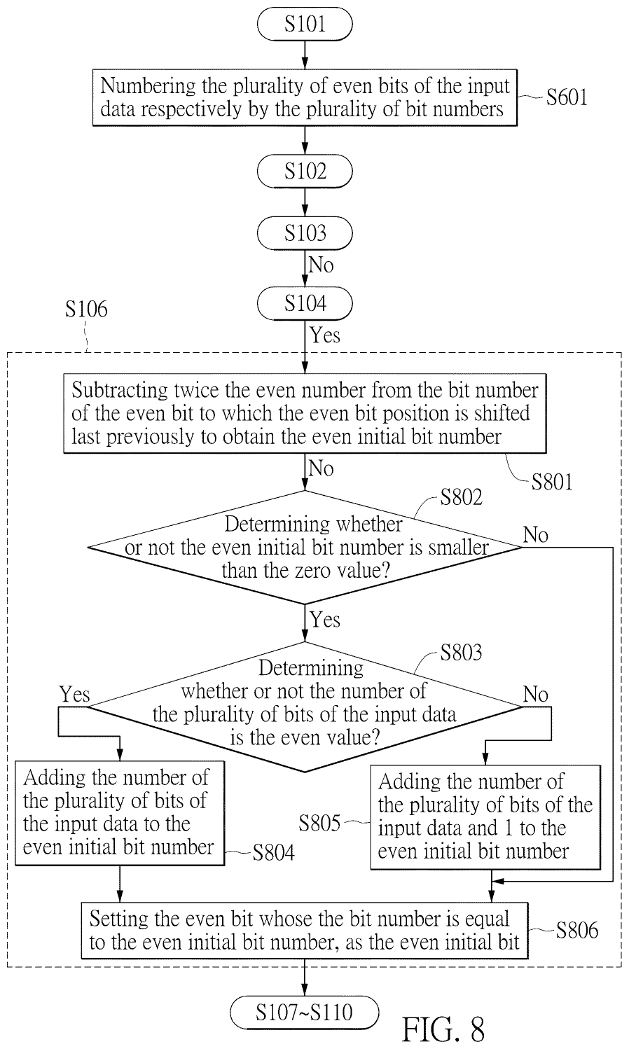

Reference is made to FIG. 8, FIG. 10, FIG. 11 and FIG. 13, in which FIG. 8 is a flowchart diagram of processes of subsequently setting the even initial bit in the odd and even bit weight equalization method according to the embodiment of the present disclosure, FIG. 10 and FIG. 11 are schematic diagrams of weight values outputted when a weight setting program is performed on the input data by the odd and even bit weight equalization method and the odd and even bit weight equalization system according to the embodiment of the present disclosure, and FIG. 13 is a block diagram of the odd and even bit weight equalization system according to the embodiment of the present disclosure.

The odd and even bit weight equalization method of the present disclosure may further include processes S801 to S806 as shown in FIG. 8.

When any one of the plurality of bit values of the plurality of even bits of the input data DT is determined equal to the first weight value in the process S104, the processes S801 to S806 included in the process S106 are performed for setting one of the plurality of even bits that is next to the even bit to which the even bit position is last shifted previously.

In the process S801, the even bit shifting circuit 1011 of the weight equalization circuit 100 subtracts twice the even number of the weight setting program performed last previously from the bit number of the even bit to which the even bit position is last shifted previously to obtain a value as the even initial bit number, which is represented by the following equation:

$$LPOS ( i ) = L P O S ( i - 1 ) - 2 \times NEVEN ( i - 1 ) ,$$

wherein LPOS(i) represents the even initial bit number (that is the bit number of the even initial bit number) of the weight setting program performed for the ith time, LPOS(i−1) represents the even initial bit number (that is the bit number of the even initial bit number) of the weight setting program performed for the (i−1)th time, i is an integer value, and NEVEN(i−1) represents the even number of the weight setting program performed for the (i−1)th time.

For example, as shown in FIG. 10 and FIG. 11, twice the even number NEVEN “1” of the weight setting program performed for the first time (TM=1) is subtracted from the even bit number LPOS “14” of the even initial bit of the weight setting program performed for the first time (TM=1) to obtain a value “12” as the even bit number LPOS of the even initial bit of the weight setting program performed for the second time (TM=2).

For example, as shown in FIG. 10 and FIG. 11, twice the even number NEVEN “1” of the weight setting program performed for the second time (TM=2) is subtracted from the even bit number LPOS “12” of the even initial bit of the weight setting program performed for the second time (TM=2) to obtain a value “10” as the even bit number LPOS of the even initial bit of the weight setting program performed for third time (TM=3).

For example, as shown in FIG. 10 and FIG. 11, twice the even number NEVEN “3” of the weight setting program performed for third time (TM=3) is subtracted from the even bit number LPOS “10” of the even initial bit of the weight setting program performed for third time (TM=3) to obtain a value “4” as the even bit number LPOS of the even initial bit of the weight setting program performed for the fourth time (TM=4).

In the process S802, the even bit shifting circuit 1011 of the weight equalization circuit 100 determines whether or not the even initial bit number is smaller than the zero value.

If the even initial bit number is not smaller than the zero value, the process S806 is then performed. Conversely, if the even initial bit number is smaller than the zero value, the process S803 is then performed.

In the process S803, the even bit shifting circuit 1011 of the weight equalization circuit 100 determines whether or not the number of the bit values of the input data DT is the even value.

If the number of the bit values of the input data DT is the even value, the processes S804 and S806. Conversely, if the number of the bit values of the input data DT is not the even value (and is the odd value), the processes S805 and S806.

In the process S804, the even bit shifting circuit 1011 of the weight equalization circuit 100 adds the number of the bit values of the input data DT to the even initial bit number, which is represented by the following equation:

$$If LPOS < 0 , LPOS = LPOS ( i ) + N ,$$

wherein LPOS(i) represents the even initial bit number obtained in the process S801, LPOS represents the even initial bit number obtained in the process S804, and N represents the number of the plurality of bits of the input data DT.

For example, as shown in FIG. 10, twice the even number NEVEN “4” of the weight setting program performed for the fourth time (TM=4) is subtracted from the even bit number LPOS “4” of the weight setting program performed for the fourth time (TM=4) to obtain a value “−4” that is smaller than a zero value (in the process S802). Therefore, the number of the plurality of bits of the input data DT “16” is added to the value “−4” to obtain a value “12” as the even bit number LPOS of the even initial bit of the weight setting program performed for the fifth time (TM=5) (in the process S804).

In the process S805, the even bit shifting circuit 1011 of the weight equalization circuit 100 adds the number of the bit values of the input data DT and a value “1” to the even initial bit number, which is represented by the following equation:

$$If LPOS < 0 = LPOS = LPOS ( i ) + ( N + 1 ) ,$$

wherein LPOS(i) represents the even initial bit number obtained in the process S801, LPOS represents the even initial bit number obtained in the process S805, and N represents the number of the plurality of bits of the input data DT.

For example, as shown in FIG. 11, twice the even number NEVEN “4” of the weight setting program performed for the fourth time (TM=4) is subtracted from the even bit number LPOS “4” of the weight setting program performed for the fourth time (TM=4) to obtain a value “−4” that is smaller than the zero value (in the process S802). Therefore, the number of the plurality of bits of the input data DT “15” and the value “1” are added to the value “−4” to obtain a value “12” as the even bit number LPOS of the even initial bit of the weight setting program performed for the fifth time (TM=5) (in the process S805).

In the process S806, the even bit shifting circuit 1011 of the weight equalization circuit 100 sets the even bit whose the bit number is equal to the even initial bit number, as the even initial bit.

After the process S806 is performed, the processes S107 to S110 are sequentially performed.

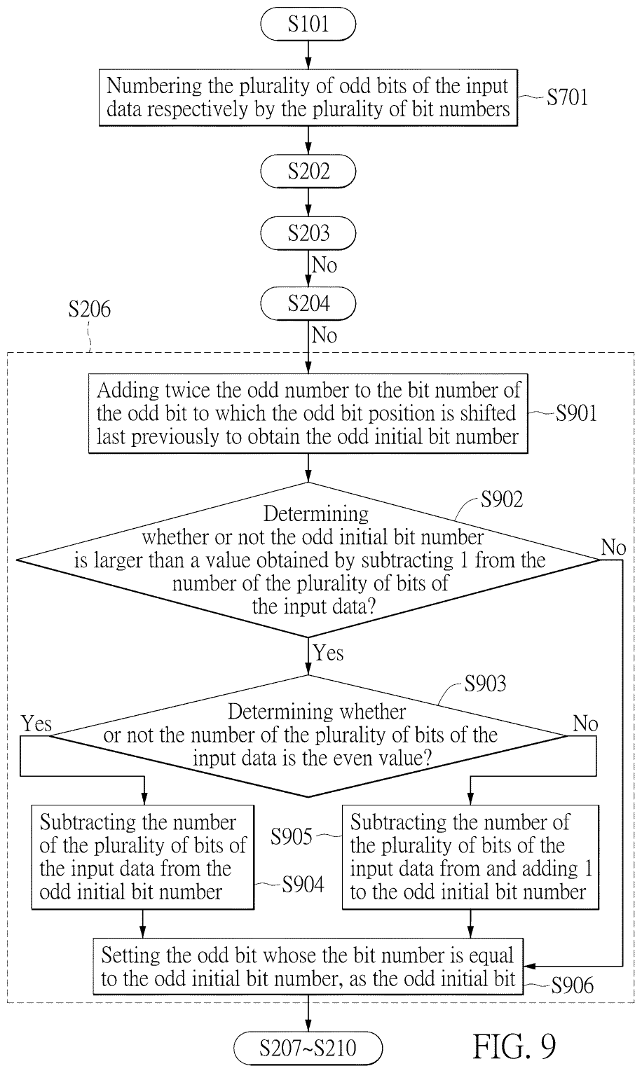

Reference is made to FIG. 9 to FIG. 11 and FIG. 13, in which FIG. 9 is a flowchart diagram of processes of subsequently setting the odd initial bit in the odd and even bit weight equalization method according to the embodiment of the present disclosure, FIG. 10 and FIG. 11 are schematic diagrams of weight values outputted when a weight setting program is performed on the input data by the odd and even bit weight equalization method and the odd and even bit weight equalization system according to the embodiment of the present disclosure, and FIG. 13 is a block diagram of the odd and even bit weight equalization system according to the embodiment of the present disclosure.

The odd and even bit weight equalization method of the present disclosure may further include processes S901 to S906 as shown in FIG. 9.

When any one of the plurality of bit values of the plurality of odd bits of the input data DT is determined equal to the first weight value in the process S204, the processes S901 to S906 included in the process S206 are performed for setting one of the plurality of odd bits that is next to the odd bit to which the odd bit position is last shifted previously.

In the process S901, the odd bit shifting circuit 1021 of the weight equalization circuit 100 adds twice the odd number of the weight setting program performed last previously to the bit number of the odd bit to which the odd bit position is last shifted previously to obtain a value as the odd initial bit number, which is represented by the following equation:

$$RPOS ( i ) = R P O S ( i - 1 ) - 2 \times N O D D ( i - 1 ) ,$$

wherein RPOS(i) represents the odd initial bit number (that is the bit number of the odd initial bit number) of the weight setting program performed ith time, RPOS(i−1) represents the odd initial bit number (that is the bit number of the odd initial bit number) of the weight setting program performed (i−1)th time, i is the integer value, and NODD(i−1) represents the odd number of the weight setting program performed (i−1)th time.

For example, as shown in FIG. 10 and FIG. 11, twice the odd number NODD “1” of the weight setting program performed for the second time (TM=2) is added to the odd bit number RPOS “1” of the odd initial bit of the weight setting program performed for the second time (TM=2) to obtain a value “3” as the odd bit number RPOS of the odd initial bit of the weight setting program performed for third time (TM=3).

For example, as shown in FIG. 10 and FIG. 11, twice the odd number NODD “2” of the weight setting program performed for third time (TM=3) is added to the odd bit number RPOS “3” of the odd initial bit of the weight setting program performed for third time (TM=3) to obtain a value “7” as the odd bit number RPOS of the odd initial bit of the weight setting program performed for the fourth time (TM=4).

In the process S902, the odd bit shifting circuit 1021 of the weight equalization circuit 100 determines whether or not the odd initial bit number is larger than a value obtained by subtracting a value “1” from the number of the plurality of bits of the input data DT.

If the odd initial bit number is not larger than the value obtained by subtracting the value “1” from the number (such as 16 shown in FIG. 10) of the plurality of bits of the input data DT, the process S906 is then performed. Conversely, if the odd initial bit number is larger than the value obtained by subtracting the value “1” from the number of the plurality of bits of the input data DT, the process S903 is then performed.

In the process S903, the odd bit shifting circuit 1021 of the weight equalization circuit 100 determines whether or not the number of the plurality of bits of the input data DT is the even value.

If the number of the plurality of bits of the input data DT is the even value, the processes S904 and S906 are sequentially performed. Conversely, if the number of the plurality of bits of the input data DT is not the even value (and is the odd value), the processes S902 and S906 are sequentially performed.

In the process S904, the odd bit shifting circuit 1021 of the weight equalization circuit 100 subtracts the odd initial bit number from the number of the plurality of bits of the input data DT, which is represented by the following equation:

$$If RPOS > ( N - 1 ) , RPOS = RPOS ( i ) - N ,$$

wherein RPOS(i) represents the odd initial bit number obtained in the process S901, RPOS represents the odd initial bit number obtained in the process S904, and N represents the number of the plurality of bits of the input data DT.

In the process S905, the odd bit shifting circuit 1021 of the weight equalization circuit 100 subtracts the odd initial bit number from and adds a value “1” to the number of the plurality of bits of the input data DT, which is represented by the following equation:

$$If RPOS > ( N - 1 ) = RPOS = RPOS ( i ) - N + 1 ,$$

wherein RPOS(i) represents the odd initial bit number obtained in the process S901, RPOS represents the odd initial bit number obtained in the process S905, and N represents the number of the plurality of bits of the input data DT.

For example, as shown in FIG. 11, the number of the plurality of bits of the input data DT is an odd value “15”. Twice the odd number NODD “4” of the weight setting program performed for the fourth time (TM=4) is added to the odd bit number RPOS “7” of the odd initial bit of the weight setting program performed for the fourth time (TM=4) to obtain a value “15” that is larger than a value “14” obtained by subtracting a value “1” from the value “15” (in the process S902). Therefore, the number “15” of the plurality of bits of the input data DT is subtracted from and a value “1” is added to the value “15” to obtain a value “1” as the odd bit number RPOS of the odd initial bit of the weight setting program performed for the fourth time (TM=5) (in the process S904).

In the process S906, the odd bit shifting circuit 1021 of the weight equalization circuit 100 sets the odd bit whose the bit number is equal to the odd initial bit number, as the odd initial bit.

After the process S906 is performed, the processes S207 to S210 are sequentially performed.

It should be understood that, in the odd and even bit weight equalization method of the present disclosure, an order of performing the processes S101 to S110 as shown in FIG. 1, the processes S202 to S210 as shown in FIG. 2, the processes S301 to S305 as shown in FIG. 3, the processes S401 to S404 as shown in FIG. 4, the processes S501 to S502 as shown in FIG. 5, the processes S601 to S605 as shown in FIG. 6, the processes S701 to S703 as shown in FIG. 7, the processes S801 to S806 as shown in FIG. 8 and the processes S901 to S906 as shown in FIG. 9 may be adjusted according to actual requirements, and the present disclosure is not limited thereto. In particular, the odd weight setting program and the even weight setting program may be synchronously performed. Alternatively, the odd weight setting program may be performed after or before the even weight setting program.

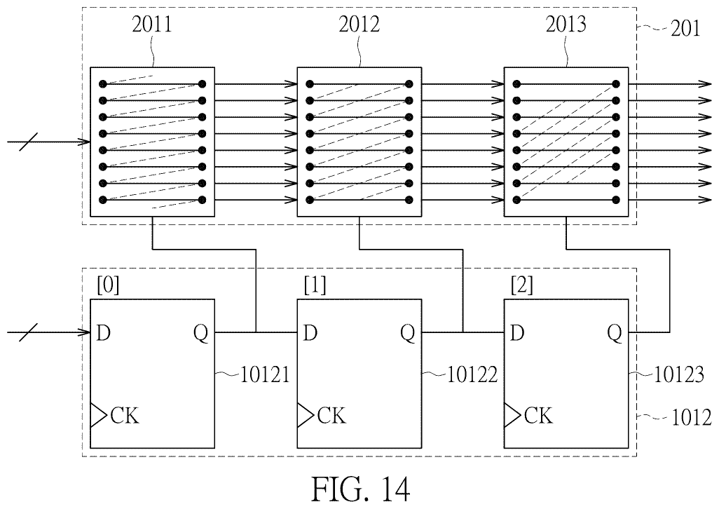

Reference is made to FIG. 14, which is a circuit diagram of an even bit shifting circuit and an even output stage circuit of the odd and even bit weight equalization system according to the embodiment of the present disclosure.

The even shifting counter circuit 1012 of the odd and even bit weight equalization system of the present disclosure as shown in FIG. 13 may include a plurality of counter circuits 10121 to 10123 such as, but not limited to, D-type flip-flops as shown in FIG. 14. In practice, the D-type flip-flops may be replaced with other flip-flops or other circuit components having the same functions. The three counter circuits 10121 to 10123 are exemplified in FIG. 14, but the present disclosure is not limited thereto. In practice, the number of the counter circuits included in the even shifting counter circuit 1012 may be adjusted according to actual requirements.

The counter circuits 10121 to 10123 correspond respectively to the plurality of bit values of the plurality of even bits of the input data DT. Each of the three counter circuits 10121 to 10123 as shown in FIG. 14 receive a corresponding one of the plurality of bit values of the plurality of even bits of the input data DT from the even bit shifting circuit 1011 as shown in FIG. 13.

Each of the three counter circuits 10121 to 10123 as shown in FIG. 14 outputs one bit value “0” or “1” each time. The three bit value that are outputted respectively by the three counter circuits 10121 to 10123 are arranged to form a binary value, and then the binary value is converted into a decimal value as the bit number of the even bit that must be adjusted to be equal to the first weight value “1”.

The output stage circuit 200 of the odd and even bit weight equalization system of the present disclosure as shown in FIG. 13 may include an even output stage circuit 201 as shown in FIG. 14. The even output stage circuit 201 may include a plurality of storage components 2011 to 2013 such as, but not limited to, registers. In practice, the registers may be replaced with other circuit components having the same functions. The three storage components 2011 to 2013 are exemplified in FIG. 14, but the present disclosure is not limited thereto. In practice, the number of the storage components included in the output stage circuit 200 may be adjusted according to actual requirements. Each of the plurality of storage components 2011 to 2013 may store one or more of the plurality of bit values of the plurality of even bits.

The storage components 2011 to 2013 may respectively store the bit values of the plurality of even bits from the counter circuits 10121 to 10123, and may respectively output the received bit values.

Reference is made to FIG. 15, which is a circuit diagram of an odd bit shifting circuit and an odd output stage circuit of the odd and even bit weight equalization system according to the embodiment of the present disclosure.

The odd shifting counter circuit 1022 of the odd and even bit weight equalization system of the present disclosure as shown in FIG. 13 may include a plurality of counter circuits 10221 to 10223 such as, but not limited to, D-type flip-flops as shown in FIG. 15. In practice, the D-type flip-flops may be replaced with other flip-flops or other circuit components having the same functions. The three counter circuits 10221 to 10223 are exemplified in FIG. 15, but the present disclosure is not limited thereto. In practice, the number of the counter circuits included in the odd shifting counter circuit 1022 may be adjusted according to actual requirements.

The counter circuits 10221 to 10223 correspond respectively to the plurality of bit values of the plurality of odd bits of the input data DT. Each of the plurality of counter circuits 10221 to 10223 as shown in FIG. 15 receives one or more of the plurality of bit values of the plurality of odd bits of the input data DT from the odd bit shifting circuit 1021 as shown in FIG. 13.

In the weight setting program performed each time, the counter circuits 10221 to 10223 as shown in FIG. 15 are configured to adjust the odd initial bit number set by the odd bit shifting circuit 1021 as shown in FIG. 13 and the other odd bits to which the odd bit position is shifted from the odd initial bit number to be equal to the first weight value such as “1”.

The output stage circuit 200 of the odd and even bit weight equalization system of the present disclosure as shown in FIG. 13 may include an odd output stage circuit 202 as shown in FIG. 15. The odd output stage circuit 202 may include a plurality of storage components 2021 to 2023 such as, but not limited to, registers. In practice, the registers may be replaced with other circuit components having the same functions. The three storage components 2021 to 2023 are exemplified in FIG. 15, but the present disclosure is not limited thereto. In practice, the number of the storage components included in the output stage circuit 200 may be adjusted according to actual requirements. Each of the plurality of storage components 2021 to 2023 may store one or more of the plurality of bit values of the plurality of odd bits.

In conclusion, the present disclosure provides the odd and even bit weight equalization method and system. In the odd and even bit weight equalization method and system of the present disclosure, the weight setting program is performed multiple times for adjusting the plurality of bit values (including the plurality of even bits and the plurality of odd bits) multiple times. As a result, the probability that each of the plurality of bit values of the input data is adjusted to be equal to the first weight value such as “1” is approximately equal to the average probability value.

If the odd and even bit weight equalization method and system of the present disclosure are applied for controlling the plurality of components, the plurality of bit values of the input data may respectively correspond to the plurality of components. The probability of turning on or using each of the plurality of components is approximately equal to the probability of turning on or using any other of the plurality of components and is approximately equal to the average probability value.

Differences between the plurality of components are often caused by variations in the manufacturing processes of the plurality of components. When signals are transmitted through the plurality of components, the signals are interfered with the differences between the plurality of components to cause errors in the signals respectively outputted by the plurality of components, resulting in poor performance of the plurality of components. However, by using the odd and even bit weight equalization method and system of the present disclosure, the probabilities that the plurality of components are turned on or used are controlled to be approximately equal to each other, such that the errors in the signals respectively outputted by the components are averaged. Therefore, by using the odd and even bit weight equalization method and system of the present disclosure, the performance of the plurality of components is improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An odd and even bit weight equalization method, which is performed by an odd and even bit weight equalization circuit, the odd and even bit weight equalization method comprising processes of:
(a) determining whether or not an even number set for a weight setting program performed each time is equal to a zero value, in response to determining that the even number set for the weight setting program performed each time is equal to the zero value, directly performing the process (d), and in response to determining that the even number set for the weight setting program performed each time is not equal to the zero value, sequentially performing the processes (b) to (d);
(b) in the weight setting program performed each time, determining whether or not any one of a plurality of bit values of a plurality of even bits of input data is equal to a first weight value, in response to determining that any one of the plurality of bit values of the plurality of even bits of the input data is not equal to the first weight value, setting one of the plurality of even bits of the input data as an even initial bit, and in response to determining that any one of the plurality of bit values of the plurality of even bits of the input data is equal to the first weight value, setting one of the plurality of even bits that is next to the even bit to which an even bit position is last shifted previously as the even initial bit;
(c) in the weight setting program performed each time, subtracting a value “1” from the even number to obtain a value as an even bit shift number, shifting the even bit position from the even initial bit to one or more of the plurality of even bits by the even bit shift number, and adjusting the even initial bit and the one or more of the plurality of even bits to be equal to the first weight value;
(d) determining whether or not an odd number set for the weight setting program performed each time is equal to a zero value, in response to determining that the odd number set for the weight setting program performed each time is equal to the zero value, returning to perform the process (a), and in response to determining that the odd number set for the weight setting program performed each time is not equal to the zero value, sequentially performing the processes (e) to (f);
(e) in the weight setting program performed each time, determining whether or not any one of a plurality of bit values of a plurality of odd bits of the input data is equal to the first weight value, in response to determining that any one of the plurality of bit values of the plurality of odd bits of the input data is not equal to the first weight value, setting one of the plurality of odd bits of the input data as an odd initial bit, and in response to determining that any one of the plurality of bit values of the plurality of odd bits of the input data is equal to the first weight value, setting one of the plurality of odd bits that is next to the odd bit to which an odd bit position is last shifted previously as the odd initial bit; and
(f) in the weight setting program performed each time, subtracting a value “1” from the odd number to obtain a value as an odd bit shift number, shifting the odd bit position from the odd initial bit to one or more of the plurality of odd bits by the odd bit shift number, adjusting the odd initial bit and the one or more of the plurality of odd bits to be equal to the first weight value, and then returning to perform the process (a).

2. The odd and even bit weight equalization method according to claim 1, further comprising processes (g) and (h) that are performed in response to determining that any one of the plurality of bit values of the plurality of even bits of the input data is equal to the first weight value in the process (b):
(g) setting each of the plurality of bit values of the input data to be equal to a second weight value; and
(h) setting the second weight value to be different from the first weight value.

3. The odd and even bit weight equalization method according to claim 2, further comprising processes (i) and (j):
(i) setting one of the second weight value and the first weight value to be equal to a value “0”; and
(j) setting the other of the second weight value and the first weight value to be equal to a value “1”.

4. The odd and even bit weight equalization method according to claim 1, further comprising processes (k) to (n) performed before the process (a) is performed:
(k) receiving the input data and a total usage number command;
(l) obtaining a plurality of total usage numbers that are respectively used in the weight setting program performed multiple times from the total usage number command;
(m) in the weight setting program performed each time, dividing the total usage number by a value “2” to obtain an arithmetic value, rounding down the arithmetic value, and setting the arithmetic value that is rounded as the odd number; and
(n) in the weight setting program performed each time, subtracting the odd number from the total usage number to obtain a value as the even number.

5. The odd and even bit weight equalization method according to claim 1, wherein the process (b) includes:
in the weight setting program performed each time, determining whether or not any one of the plurality of bit values of the plurality of even bits of the input data is equal to the first weight value, in response to determining that any one of the plurality of bit values of the plurality of even bits of the input data is not equal to the first weight value, setting a highest one of the plurality of even bits of the input data as the even initial bit, and in response to determining that any one of the plurality of bit values of the plurality of even bits of the input data is equal to the first weight value, setting one of the plurality of even bits of the input data that is a next lower even bit of the even bit to which the even bit position is last shifted previously as the even initial bit.

6. The odd and even bit weight equalization method according to claim 1, wherein the process (e) includes:
in the weight setting program performed each time, determining whether or not any one of the plurality of bit values of the plurality of odd bits of the input data is equal to the first weight value, in response to determining that any one of the plurality of bit values of the plurality of odd bits of the input data is not equal to the first weight value, setting a lowest one of the plurality of odd bits of the input data as the odd initial bit, and in response to determining that any one of the plurality of bit values of the plurality of odd bits of the input data is equal to the first weight value, setting one of the plurality of odd bits that is a next higher odd bit of the odd bit to which the odd bit position is last shifted previously as the odd initial bit.

7. The odd and even bit weight equalization method according to claim 1, further comprising a process (o) performed before the process (a) is performed:
(o) numbering the plurality of odd bits and the plurality of even bits of the input data sequentially from a lowest bit to a highest bit among the plurality of bit values of the input data, with the plurality of bit serial numbers.

8. The odd and even bit weight equalization method according to claim 7, further comprising processes (p) and (q) that are performed in response to determining that any one of the plurality of bit values of the plurality of even bits of the input data is not equal to the first weight value in the process (b):
(p) determining whether or not a number of the plurality of bits of the input data is an even value, in response to determining that the number of the plurality of bits of the input data is the even value, subtracting a value “2” from the number of the plurality of bits of the input data to obtain a value as an even initial bit number, and in response to determining that the number of the plurality of bits of the input data is not the even value, subtracting a value “1” from the number of the plurality of bits of the input data to obtain a value as the even initial bit number; and
(q) setting the even bit with the bit number being equal to the even initial bit number, as the even initial bit.

9. The odd and even bit weight equalization method according to claim 8, further comprising processes (r) and (s) performed in response to determining that any one of the plurality of bit values of the plurality of odd bits of the input data is not equal to the first weight value in the process (e);
(r) setting an odd initial bit number to be equal to a value “1”; and
(s) setting the odd bit with the bit number being equal to the odd initial bit number, as the odd initial bit.

10. The odd and even bit weight equalization method according to claim 9, further comprising processes (t) and (u) performed in response to determining that any one of the plurality of bit values of the plurality of even bits of the input data is equal to the first weight value in the process (b);
(t) in the weight setting program performed each time, subtracting twice the even number of the weight setting program performed last previously from the bit number of the even bit to which the even bit position is last shifted previously to obtain a value as the even initial bit number; and
(u) in the weight setting program performed each time, setting the even bit with the bit number being equal to the even initial bit number, as the even initial bit.

11. The odd and even bit weight equalization method according to claim 10, further comprising processes (v) to (w) performed after the process (b) is performed:
(v) determining whether or not the even initial bit number is smaller than a zero value, in response to determining that the even initial bit number is not smaller than the zero value, not performing the process (w), and in response to determining that the even initial bit number is smaller than the zero value, performing the process (w); and
(w) determining whether or not the number of the plurality of bits of the input data is the even value, in response to determining that the number of the plurality of bits of the input data is the even value, adding the number of the plurality of bits of the input data to the even initial bit number, and in response to determining that the number of the plurality of bits of the input data is not the even value, adding the number of the plurality of bits of the input data and a value “1” to the even initial bit number.

12. The odd and even bit weight equalization method according to claim 11, further comprising processes (x) and (y) performed in response to determining that any one of the plurality of bit values of the plurality of odd bits of the input data is equal to the first weight value in the process (e);
(x) in the weight setting program performed each time, adding twice the odd number of the weight setting program performed last previously to the bit number of the odd bit to which the odd bit position is last shifted previously to obtain a value as the odd initial bit number; and
(y) in the weight setting program performed each time, setting the odd bit with the bit number being equal to the odd initial bit number, as the odd initial bit.

13. The odd and even bit weight equalization method according to claim 12, further comprising processes (z) to (bb) performed after the process (e) is performed:
(z) subtracting a value “1” from the number of the plurality of bits of the input data to obtain a value;
(aa) determining whether or not the odd initial bit number is larger than the value obtained by subtracting the value “1” from the number of the plurality of bits of the input data, in response to determining that the odd initial bit number is not larger than the value obtained by subtracting the value “1” from the number of the plurality of bits of the input data, not performing the process (bb), and in response to determining that the odd initial bit number is larger than the value obtained by subtracting the value “1” from the number of the plurality of bits of the input data, performing the process (bb); and
(bb) determining whether or not the number of the plurality of bits of the input data is the even value, in response to determining that the number of the plurality of bits of the input data is the even value, subtracting the number of the plurality of bits of the input data from the odd initial bit number, and in response to determining that the number of the plurality of bits of the input data is not the even value, subtracting the number of the plurality of bits of the input data from the odd initial bit number and adding a value “1” to the odd initial bit number.

14. The odd and even bit weight equalization method according to claim 1, further comprising processes (cc) and (dd) performed after the process (f) is performed:
(cc) setting the plurality of bit values of the input data to correspond to a plurality of components, respectively; and
(dd) determining whether or not each one of the plurality of bit values of the input data is equal to the first weight value, in response to determining that the one of the plurality of bit values of the input data is not equal to the first weight value, turning off the component corresponding to the one of the plurality of bit values of the input data, and in response to determining that the one of the plurality of bit values of the input data is equal to the first weight value, turning on the component corresponding to the one of the plurality of bit values of the input data.

15. An odd and even bit weight equalization system, comprising:
a weight equalization circuit configured to perform a weight setting program multiple times;
wherein, in the weight setting program performed for a first time, the weight equalization circuit sets any one of a plurality of even bits of input data as an even initial bit, and in the weight setting program performed for other times, the weight equalization circuit sets one of the plurality of even bits that is next to the even bit to which the even bit position is last shifted previously as the even initial bit;
wherein, when an even number set for the weight setting program performed each time is not equal to a zero value, the weight equalization circuit subtracts a value “1” from the even number to obtain a value as an even bit shift number, shifts an even bit position from the even initial bit to one or more of the plurality of even bits by the even bit shift number, and adjusts the even initial bit and the one or more of the plurality of even bits to be equal to a first weight value;
wherein, in the weight setting program performed for the first time, the weight equalization circuit sets any one of a plurality of odd bits of the input data as an odd initial bit, and in the weight setting program performed for other times, the weight equalization circuit sets the bit value of one of the plurality of odd bits that is next to the odd bit to which the odd bit position is last shifted previously as the odd initial bit;
wherein, when an odd number set for the weight setting program performed each time is not equal to the zero value, the weight equalization circuit subtracts a value “1” from the odd number to obtain a value as an odd bit shift number, shifts an odd bit position from the odd initial bit to one or more of the plurality of odd bits by the odd bit shift number, and adjusts the odd initial bit and the one or more of the plurality of odd bits to be equal to the first weight value.

16. The odd and even bit weight equalization system according to claim 15, wherein, before the even bit position and the odd bit position are shifted in the weight setting program performed each time, the weight equalization circuit sets each of the plurality of bit values of the input data to be equal to a second weight value.

17. The odd and even bit weight equalization system according to claim 15, wherein the weight equalization circuit sets the plurality of bit values of the input data to correspond to a plurality of components, respectively;
wherein the weight equalization circuit turns on the component corresponding to the bit value being equal to the first weight value;
wherein the weight equalization circuit turns off the component corresponding to the bit value that is not equal to the first weight value.

18. The odd and even bit weight equalization system according to claim 15, wherein in the weight setting program performed each time, the weight equalization circuit divides a total usage number by a value “2” to obtain an arithmetic value, rounds down the arithmetic value, sets the arithmetic value that is rounded as the odd number, and subtracts the odd number from the total usage number to obtain a value as the even number.

19. The odd and even bit weight equalization system according to claim 15, wherein the weight equalization circuit includes:
an even bit shifting circuit configured to set the even initial bit number, count and set the even bit shift number, and shift the even bit position from the even initial bit to one or more of the plurality of even bits by the even bit shift number;
an even shifting counter circuit connected to the even bit shifting circuit and an output stage circuit, and configured to count up the even initial bit and the one or more of the plurality of even bits to be equal to the first weight value;
an odd bit shifting circuit configured to set the odd initial bit, count and set the odd bit shift number, and shifts the odd bit position from the odd initial bit to one or more of the plurality of odd bits by the odd bit shift number; and
an odd shifting counter circuit connected to the odd bit shifting circuit and the output stage circuit, and configured to count up the odd initial bit and the one or more of the plurality of odd bits to be equal to the first weight value;
wherein the output stage circuit stores the input data that is counted.

20. The odd and even bit weight equalization system according to claim 19, wherein the output stage circuit outputs the plurality of bit values of the input data that is counted respectively to a plurality of components.
